(19) United States
(12) Patent Application Publication
(10) Pub. No.: US 2009/0085778 A1
(43) Pub. Date: Apr. 2, 2009

(54) TEXT INPUT DEVICE FOR VIDEOGAME CONTROLLER

(75) Inventors: John K. Ikeda, Seattle, WA (US); Michael Wesley Baseflug, Duvall, WA (US); Eric Wahl, Kirkland, WA (US); Jared Randall, Seattle, WA (US)

Correspondence Address: WOODCOCK WASHBURN LLP (MICROSOFT CORPORATION), CIRA CENTRE, 12TH FLOOR, 2929 ARCH STREET, PHILADELPHIA, PA, 19104-2891, US

(73) Assignee: Microsoft Corporation, Redmond, WA (US)

(21) Appl. No.: 11/866,234

(22) Filed: Oct. 2, 2007

(51) Int. Cl. H03M 11/00

(52) U.S. Cl. 341/22

(57) ABSTRACT

A text input device for videogame controller may comprise a text input device housing comprising a keypad. The text input device housing forms a friction-fitting cavity for engaging the videogame controller. An electrical interface plug can be disposed inside the friction-fitting cavity, and can engage with a socket on the videogame controller when the text input device is engaged. The electrical interface plug transmits electrical signals to and from the videogame controller.

### BACKGROUND

Videogame systems have experienced tremendous technological advancement in recent years. The capabilities of videogame consoles have expanded to include networked gaming modes, wireless communications, and high-resolution graphics processing. Some consoles are beginning to offer general computing capabilities such as word processing and internet and email access. It is likely that as video gaming technologies continue to improve, such expanded and more “general purpose” uses will continue to emerge.

The input device of choice for videogame consoles has traditionally been a videogame controller. A videogame controller may have a variety of action buttons, triggers, and thumbsticks that allow navigation and selection of features. As the capabilities of videogame systems expand, however, it is useful to also expand the capabilities of videogame controllers. Moreover, because of the multipurpose uses for videogame controllers, the capabilities of videogame controllers are advantageously expanded in a ergonomic and detachable manner.

### SUMMARY

A text input device for videogame controller in accordance with an embodiment of the invention may comprise a text input device housing comprising a keypad. The text input device housing forms a friction-fitting cavity for engaging the videogame controller. An electrical interface plug can be disposed inside the friction-fitting cavity, and can engage with a socket on the videogame controller when the text input device is engaged. The electrical interface plug transmits electrical signals to and from the videogame controller.

In one embodiment, the text input device housing may comprise a top housing comprising a keypad and a bottom housing disposed underneath said top housing, the top and bottom housings forming a friction-fitting cavity for engaging the videogame controller. Furthermore, the electrical interface plug can be angularly moveable about a pivot disposed inside said text input device.

Other advantages and features of the invention are described below.

### BRIEF DESCRIPTION OF THE DRAWINGS

The systems and methods for a text input device for videogame controller in accordance with the present invention are further described with reference to the accompanying drawings in which:

FIG. 1 illustrates a top view of an exemplary videogame controller with attached text input device.

FIG. 2 illustrates a bottom view of an exemplary videogame controller with attached text input device.

FIG. 3 illustrates a side view of an exemplary videogame controller with attached text input device.

FIG. 4 illustrates a top view of an exemplary videogame controller without attached text input device.

FIG. 5 illustrates a bottom view of an exemplary videogame controller without attached text input device.

FIG. 6 illustrates a side view of an exemplary videogame controller without attached text input device.

FIG. 7 illustrates a top view of an exemplary text input device.

FIG. 8 illustrates a bottom view of an exemplary text input device.

FIG. 9 illustrates a side view of an exemplary text input device.

FIG. 10 illustrates a back view of an exemplary text input device.

FIG. 11 illustrates a back/bottom view of an exemplary text input device.

FIG. 12 illustrates a view inside an exemplary text input device.

### DETAILED DESCRIPTION

Certain specific details are set forth in the following description and figures to provide a thorough understanding of various embodiments of the invention. Certain well-known details often associated with computing and software technology and electrical device manufacture are not set forth in the following disclosure, however, to avoid unnecessarily obscuring the various embodiments of the invention. Further, those of ordinary skill in the relevant art will understand that they can practice other embodiments of the invention without one or more of the details described below.

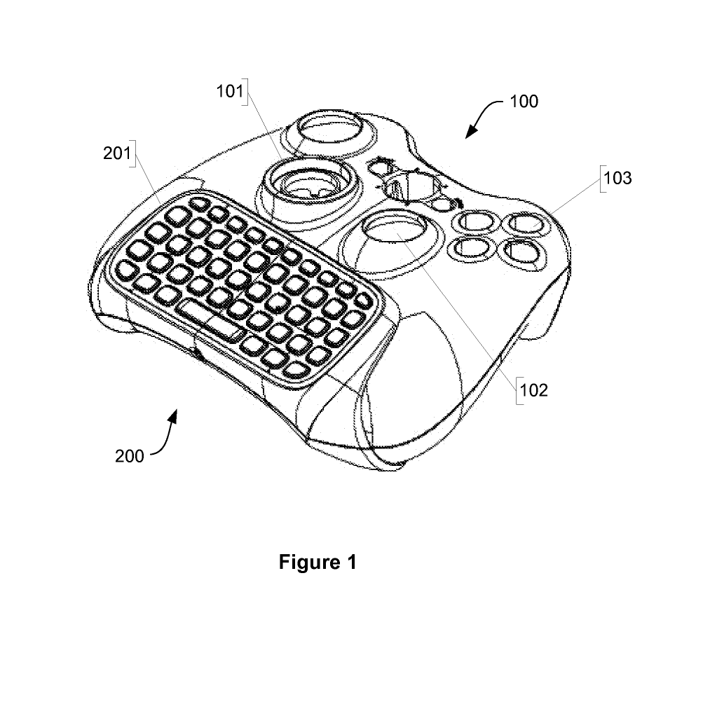

FIG. 1 illustrates a top view of an exemplary videogame controller 100 with attached text input device 200. Text input device 200 may comprise keypad 201, which may comprise, for example, a QWERTY keypad with additional function keys as desired. Keypads in non-QWERTY arrangements are also known in the art and may be used.

Videogame controller 100 may comprise, for example, thumbsticks 101, 102, and action buttons 103. Videogame controller 100 may be arranged in a variety of shapes and sizes, and may be equipped with controls of a variety of types. For example, some videogame controllers are in a more “joystick” type formation. Some have triggers positioned underneath the videogame controller 100 as an additional means of input. The illustrated videogame controller 100 is a two-handed type presently popular for use with the XBOX® console made by MICROSOFT® Corporation of Redmond, Wash.

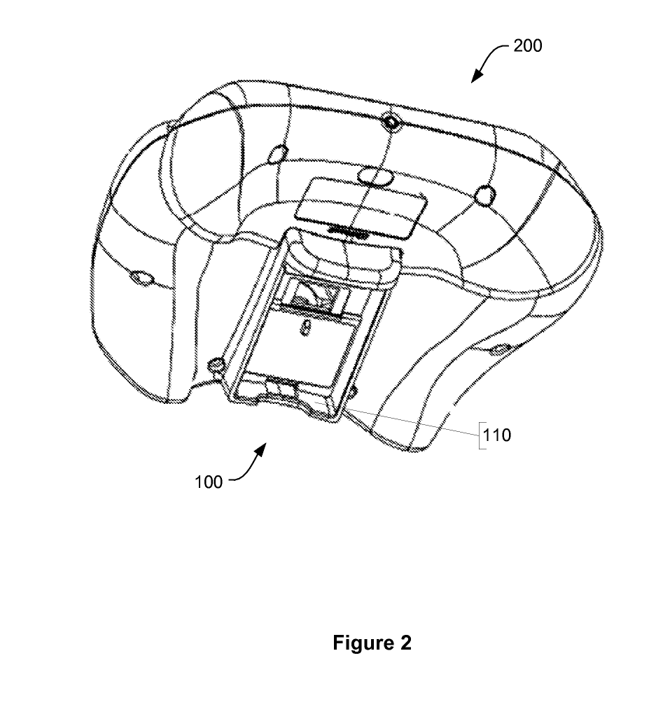

FIG. 2 illustrates a bottom view of an exemplary videogame controller 100 with attached text input device 200. Seen underneath the controller 100 is a battery and wireless communications housing 110. Videogame controller 100 may comprise wireless communications functionality for communication with a console unit, or may connect to such console unit using a wire, cable, or other transmission means. Inputs to the text input device 200 are received via the keypad 201 illustrated in FIG. 1, and outputs of the text input device 200 are transmitted to a console via the videogame controller 100 to a videogame console using such transmission means.

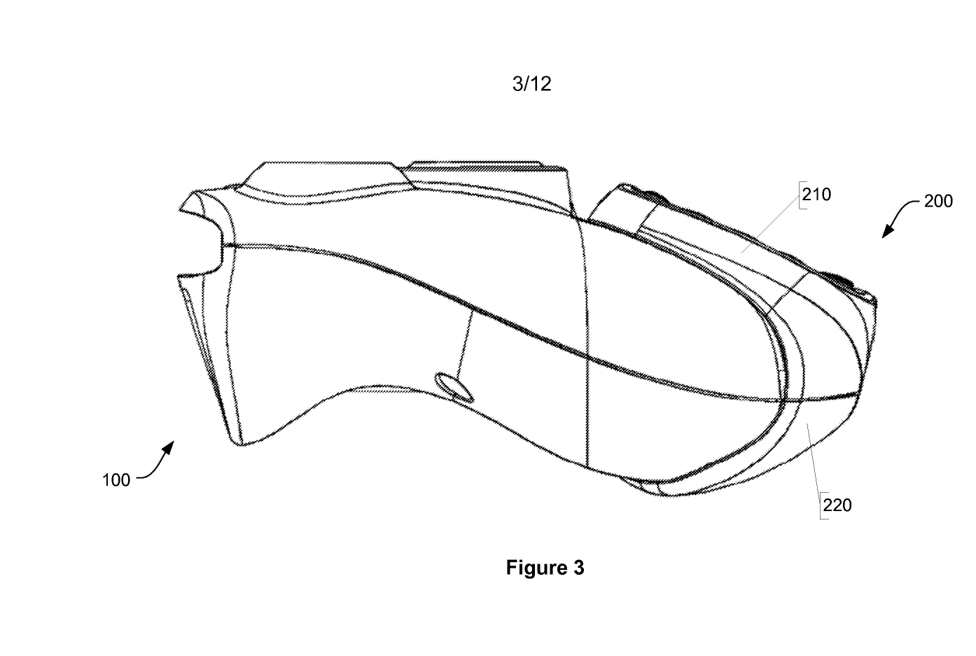

FIG. 3 illustrates a side view of an exemplary videogame controller 100 with attached text input device 200. A review of FIGS. 1, 2, and 3 demonstrates that in the illustrated embodiments, friction forces alone are strong enough to hold the text input device 200 in place while it is engaged with the videogame controller 100. Straps, buckles, snaps, clips, Velcro and other mechanisms are not necessary. While such other attaching mechanisms are available for use in some embodiments, preferred embodiments retain simplicity as illustrated in these Figures.

FIG. 3 illustrates a text input device housing comprising, for example, a top housing 210 and a bottom housing 220. Top housing 210 and bottom housing 220 may be manufactured as separate pieces or as a single piece. A top housing 210 is defined as a portion of a text input device 200 that fricatively engages with a top side of videogame controller 100. Conversely, a bottom housing 220 is defined as a portion of a text input device 200 that fricatively engages with a bottom side of videogame controller 100.

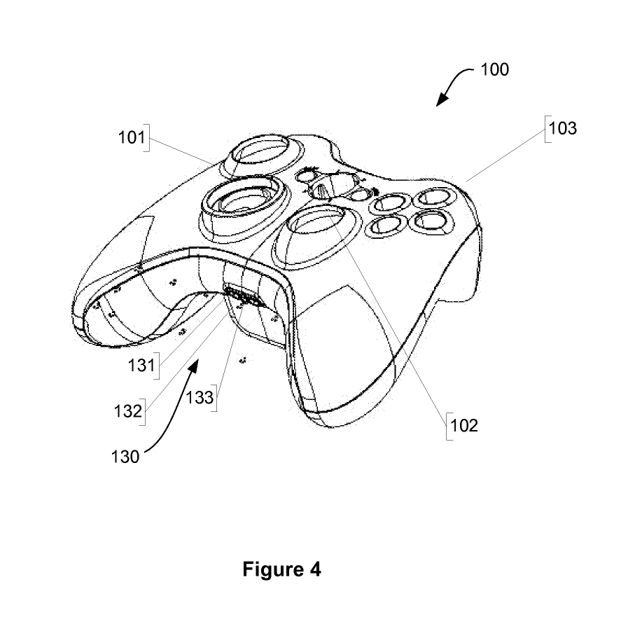

FIG. 4 illustrates a top view of an exemplary videogame controller 100 without attached text input device. Here, the two-handed controller embodiment is clearly shown. In such embodiments, the videogame controller 100 may comprise right and left hand grips and a depression on the underside of the controller 100 where fingers fit comfortably. In illustrated embodiments, the text input device 200 may be similarly contoured to extend the hand grips and finger-depression, thereby matching and extending the ergonomic design of the controller 100. In the case of other controller shapes, the text input device 200 may similarly match and extend the contours to successfully ergonomically integrate with the controller. In the illustrated embodiments, matching the shape of the controller 100 allows the text input device 200 to friction-fit to the controller 100. The curved shape of the text input device accessory 200 nests into one edge of the controller 100.

FIG. 4 also illustrates a socket 130 comprising exemplary electrical interface receivers 131, 132, 133. These receivers 131-133 receive the electrical interface plug protruding from the text input device 200, illustrated below.

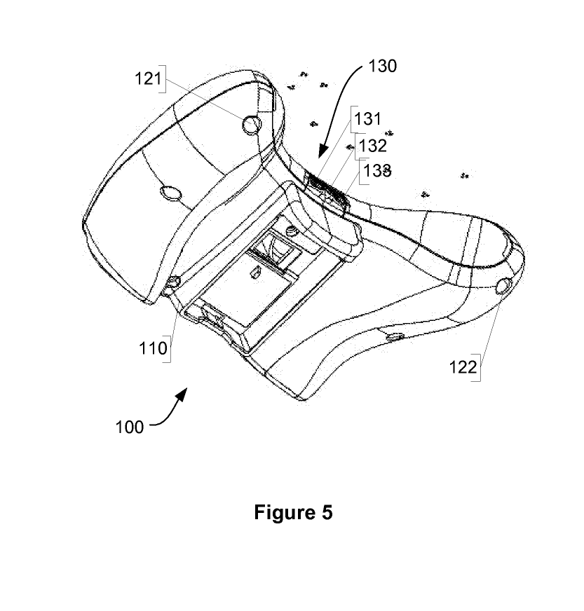

FIG. 5 illustrates a bottom view of an exemplary videogame controller 100 without attached text input device. Another view of the receivers 131-133 is provided, and the two-handed embodiment comprising side-grips and finger-depression is further elucidated.

FIG. 5 illustrates recessed screw bosses 121-122 in the videogame controller 100. In one embodiment the text input device 200 can take advantage of such recessed screw bosses 121-122 with a friction plug member that fits into such recessed screw bosses 121-122, as illustrated below.

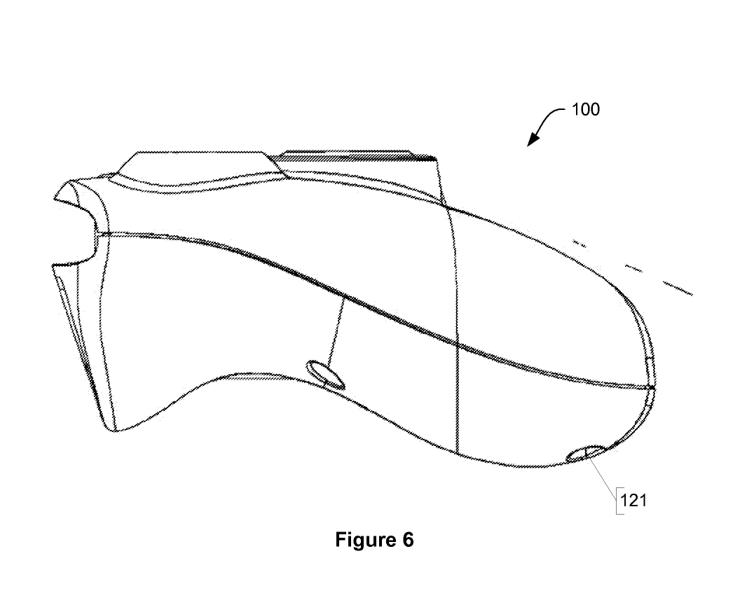

FIG. 6 illustrates a side view of an exemplary videogame controller 100 without attached text input device. Again, a recessed screw boss 121 is visible. FIG. 6 is advantageously compared with FIG. 3, which illustrates the side view of exemplary videogame controller 100 with the attached text input device 200.

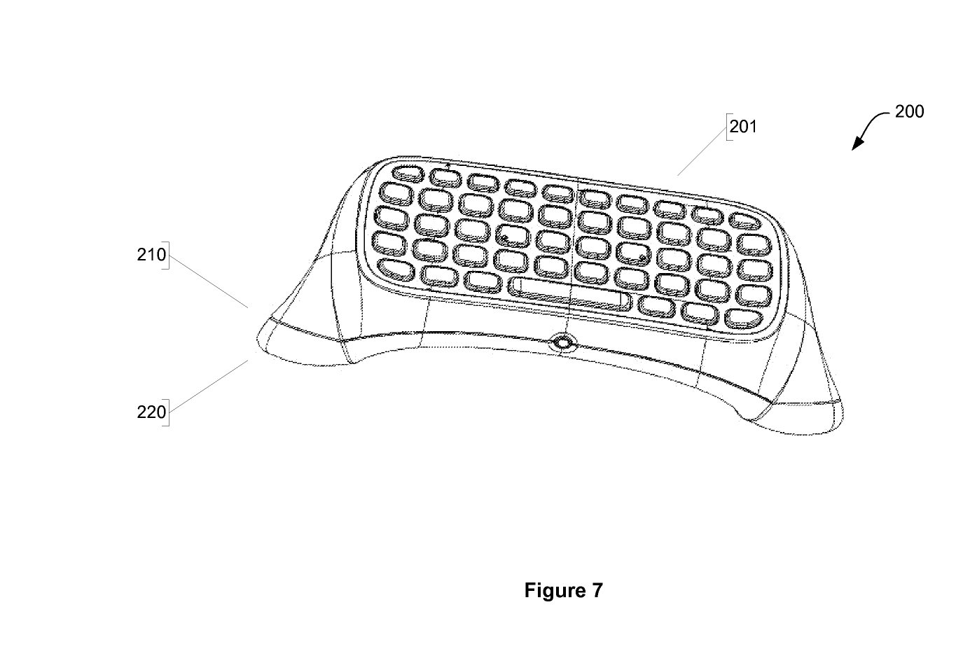

FIG. 7 illustrates a top view of an exemplary text input device 200. Keypad 201, top housing 210, and bottom housing 220 are shown. FIG. 7 is advantageously compared with FIG. 1, which illustrates the top view of exemplary text input device 200 attached to videogame controller 100.

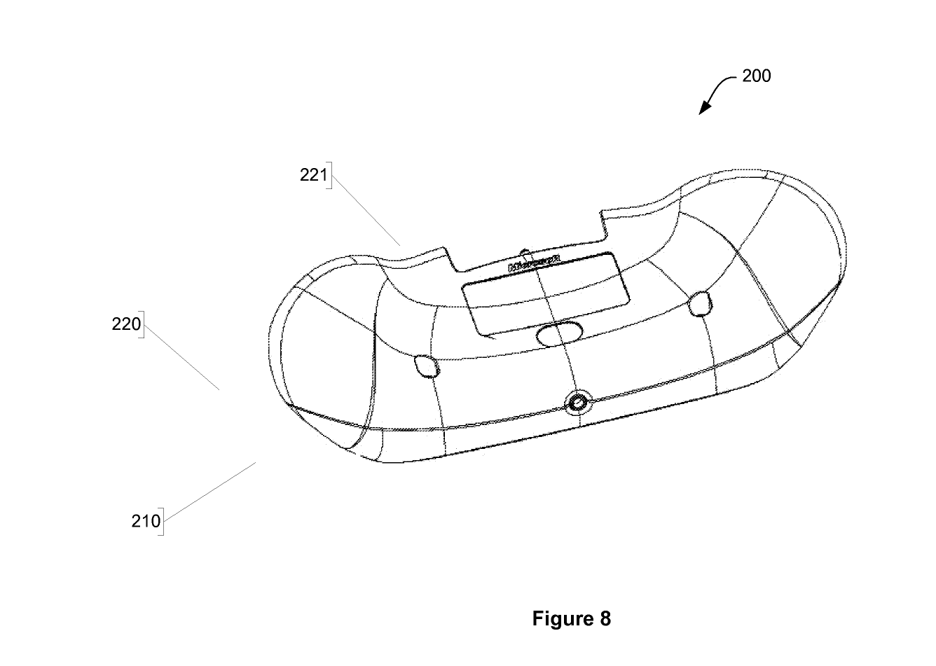

FIG. 8 illustrates a bottom view of an exemplary text input device 200. Again, the housing comprising top housing 210 and bottom housing 220 is illustrated. Here, a portion 221 of the bottom housing 220 is designated as a portion that flexes when the text input device is engaged with a videogame controller 100. In this embodiment, portion 221 is constructed from a plastic material that is thin enough and also shaped in a manner that allows it to flex outward as the text input device 200 is engaged with the videogame controller 100. This flexing allows friction plug members fits to snap into recessed screw bosses 121-122, and thereby form a tight friction-fit between the text input device 200 and the videogame controller 100. The friction-fit is ideally strong enough to allow for typing on the keypad 201 without accidentally disengaging the text input device 200 from the videogame controller 100, but not so strong that the text input device 200 cannot be intentionally removed by pulling on the text input device 200 at an appropriate angle.

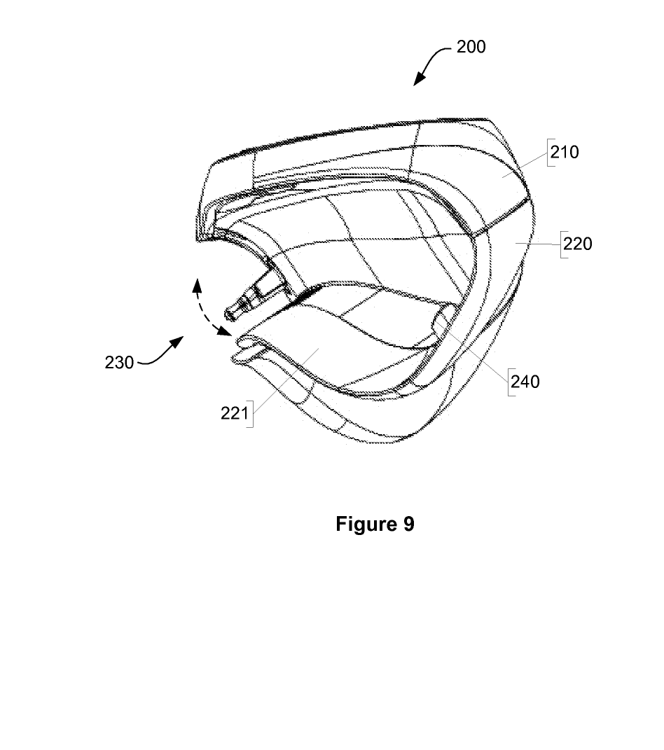

FIG. 9 illustrates a side view of an exemplary text input device 200. Here, the housing comprising top housing 210 and bottom housing 220 forms a friction-fitting cavity for engaging the videogame controller 100. Electrical interface plug 230 is disposed inside the cavity, and the cavity is defined by an edge extending from the top, sides, and bottom of the text input device 200. The flexible portion 221 discussed above may be disposed along the edge of the friction-fitting cavity, as may friction plug members such as 240.

As suggested by the dotted line proximal to electrical interface plug 230, the electrical interface plug 230 may be angularly moveable. In one embodiment, it is moveable about a pivot disposed inside said text input device 200.

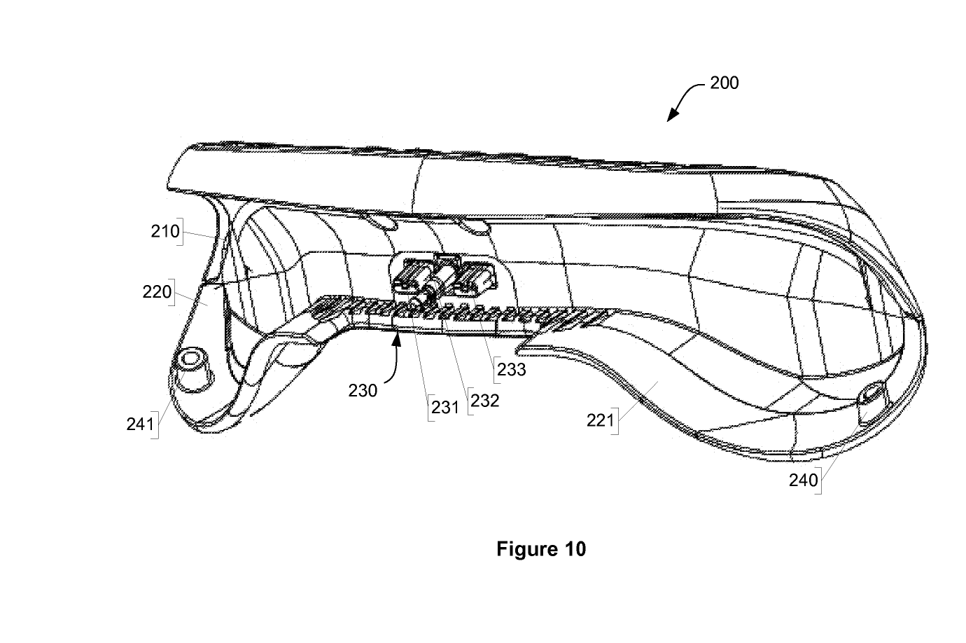

FIG. 10 illustrates a back view of an exemplary text input device 200. Again, a housing comprising top housing 210 and bottom housing 220 is illustrated, said housing forming a friction-fitting cavity for engaging a videogame controller. An electrical interface plug 230 is disposed inside the friction-fitting cavity. The electrical interface members 231, 232, and 233 of plug 230 engage with a socket 130 on the videogame controller 100 as illustrated in FIGS. 4 and 5. The electrical interface members 231, 232, and 233 transmit electrical signals from text input device 200 to the videogame controller 100.

The electrical interface members 231, 232, and 233 may be designed for blind mating to the controller 100. To accomplish this, the members 231, 232, and 233 may be formed in nesting shapes such as the equilateral triangular shape of members 231 and 233, and the conical shape of member 232. Also, embodiments in which electrical interface plug 230 is angularly moveable provide better blind mating, because the plug 230 initially connect with socket 130 while plug is in a first position, and can rotate into an engaged position as the text input device 200 is slideably engaged with the videogame controller 100.

FIG. 10 also illustrates friction plug members 240-241 disposed along an edge of the friction-fitting cavity that can engage with recessed screw bosses 121-122, and a portion 221 of the text input device housing, also disposed along an edge of the friction-fitting cavity, that flexes when the text input device 200 is engaged with a videogame controller 100.

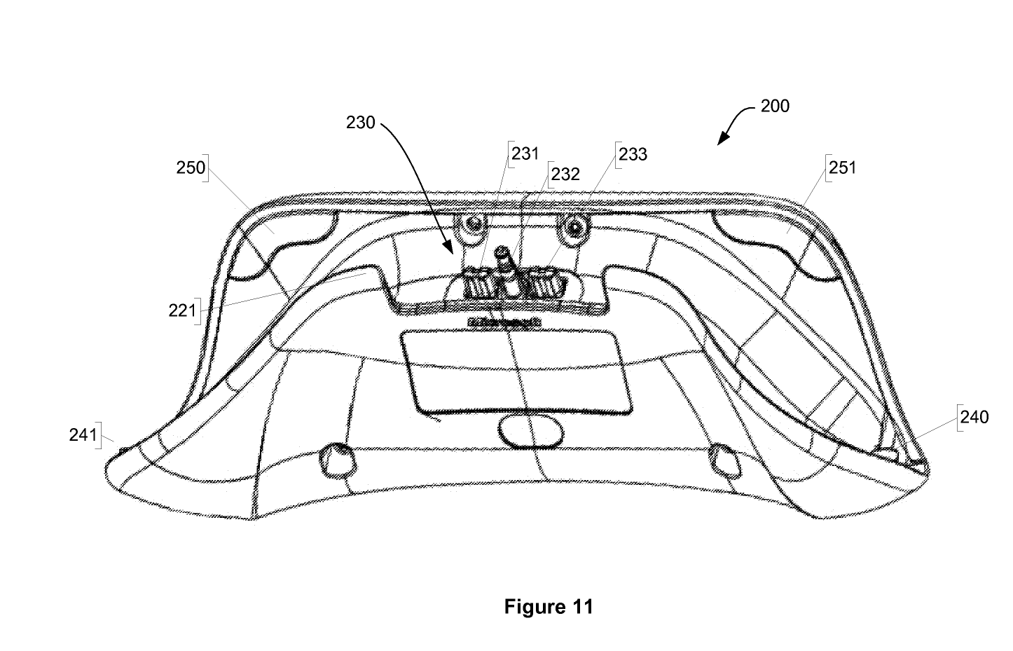

FIG. 11 illustrates a back/bottom view of an exemplary text input device 200. Again, friction plug members 240-241, electrical interface plug 231 comprising electrical interface members 231-233, and flexible portion 221 are designated. This view also illustrates friction pad members 250 and 251 disposed on an edge of the friction-fitting cavity. Here, friction pad members 250 and 251 are disposed opposite the friction plugs 240 and 241, the friction pad members 250 and 251 being disposed on the edge of the top housing and the friction plugs 240 and 241 being disposed on the edge of the bottom housing 220. Friction pad members 250 and 251 may be made from any enhanced friction material, for example rubber.

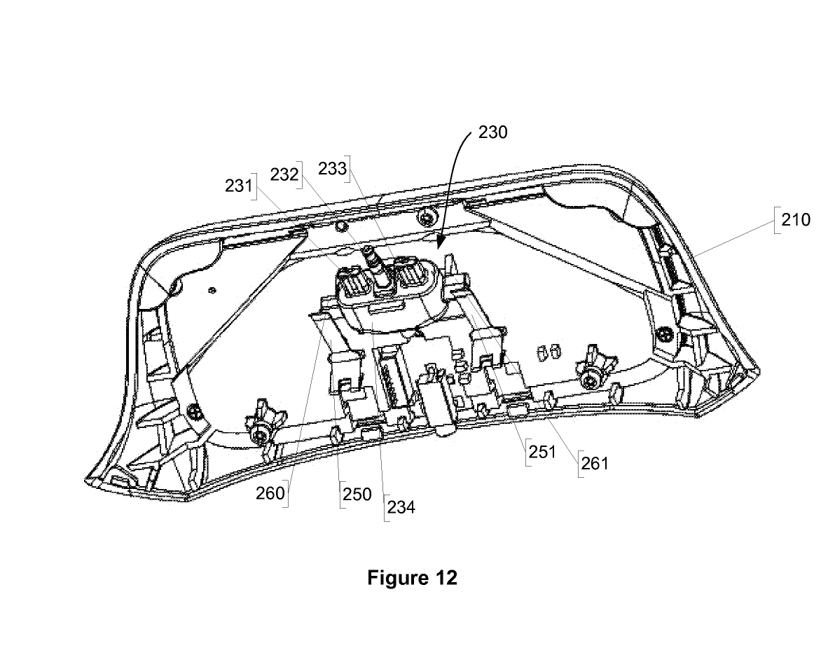

FIG. 12 illustrates a view inside an exemplary text input device 200. Top housing 210 is shown, while bottom housing 220 is removed. As illustrated, the electrical interface plug 230 may comprise a plug body 234 and electrical interface members 231-233. The electrical interface plug 230 is angularly moveable about a pivot disposed inside said text input device 200. In the illustrated embodiment, the pivot comprises arms 260, 261 extending from said plug body 234. Means for returning the electrical interface plug 230 to a first position are also illustrated as 250 and 251. Here, such means comprise metal elements placed in fricative contact with arms 260, 261, so as to apply pressure on the arms and thereby achieve the desired return rotation of the plug 230. Other means are also possible, for example spring or magnet means might also be utilized.

In light of the diverse controller shapes and configurations that may be built, the text input device provided herein cannot be construed as limited in any way to a particular architecture. Instead, the present invention should not be limited to any single embodiment, but rather should be construed in breadth and scope in accordance with the appended claims.

1. A text input device for a videogame controller, comprising:
a top housing comprising a keypad;
a bottom housing disposed underneath said top housing; and
said top housing and said bottom housing forming a friction-fitting cavity for engaging said videogame controller.

2. The text input device of claim 1, further comprising an electrical interface plug disposed inside said friction-fitting cavity.

3. The text input device of claim 1, wherein said electrical interface plug is angularly moveable about a pivot disposed inside said text input device.

4. The text input device of claim 1, further comprising a friction pad member disposed on an edge of said friction-fitting cavity.

5. The text input device of claim 1, wherein at least one edge of said friction-fitting cavity flexes when said text input device is engaged with said videogame controller.

6. The text input device of claim 1, further comprising a friction plug member disposed on an edge of said friction-fitting cavity.

7. The text input device of claim 6, wherein said friction plug member engages a recessed screw boss on said videogame controller.

8. A text input device for a videogame controller, comprising:
a text input device housing comprising a keypad;
said text input device housing forming a friction-fitting cavity for engaging said videogame controller; and
an electrical interface plug disposed inside said friction-fitting cavity, said electrical interface engaging with a socket on said videogame controller and transmitting electrical signals from said text input device to said videogame controller.

10. The text input device of claim 9, wherein said electrical interface plug is angularly moveable about a pivot disposed inside said text input device.

11. The text input device of claim 9, further comprising a friction pad member disposed on an edge of said friction-fitting cavity.

12. The text input device of claim 9, wherein at least one edge of said friction-fitting cavity flexes when said text input device is engaged with said videogame controller.

13. The text input device of claim 9, further comprising a friction plug member disposed on an edge of said friction-fitting cavity.

14. A text input device for a videogame controller, comprising:
a text input device housing comprising a keypad; and
an electrical interface plug, said electrical interface plug engaging with a socket on said videogame controller and transmitting electrical signals from said text input device to said videogame controller, wherein said electrical interface plug is angularly moveable about a pivot disposed inside said text input device.

15. The text input device of claim 14, wherein said electrical interface plug comprises a plug body and at least one electrical interface member.

16. The text input device of claim 15, wherein said pivot comprises arms extending from said plug body.

17. The text input device of claim 14, further comprising means for returning said electrical interface plug to a first position.

18. The text input device of claim 14, further comprising a friction pad member disposed on an edge of said friction-fitting cavity.

19. The text input device of claim 14, wherein at least one edge of said friction-fitting cavity flexes when said text input device is engaged with said videogame controller.

20. The text input device of claim 14, further comprising a friction plug member disposed on an edge of said friction-fitting cavity.
